(19) United States
(12) Patent Application Publication
(10) Pub. No.: US 2008/0002452 A1
(43) Pub. Date: Jan. 3, 2008

(54) Method for setting a read voltage, and semiconductor circuit arrangement

(76) Inventors: Uwe Augustin, Dresden (DE); Gert Koebernik, Munic (DE); Mirko Reissmann, Ottendorf-Okrilla (DE)

Correspondence Address: SLATER & MATSIL, L.L.P., 17950 PRESTON ROAD, SUITE 1000, DALLAS, TX, 75252, US

(21) Appl. No.: 11/716,381

(22) Filed: Mar. 9, 2007

(30) Foreign Application Priority Data
Mar. 9, 2006 (DE) 10 2006 010 979.1

(51) Int. Cl. G11C 7/06; G11C 11/34; H01F 21/00

(52) U.S. Cl. 365/103; 365/174; 365/189.07

(57) ABSTRACT

A method for setting a read voltage that is used to read data from a nonvolatile memory is disclosed. Logic states from the first state set are stored in a particular number of digits in the multiplicity of memory areas. The memory areas are read in succession. The operation of reading one of the memory areas involves a number of reading steps for reading state information the read voltage being varied for each reading step and the state information that has been read being provided after each reading step. Control information based on the particular number of digits is provided. The state information that has been provided is compared with the control information. The read voltage to be set or a read voltage range to be set is determined on the basis of the results of the comparison.

This application claims priority to German Patent Application 10 2006 010 979.1, which was filed Mar. 9, 2006 and is incorporated herein by reference.

### TECHNICAL FIELD

The invention relates to a method for setting a read voltage and to a semiconductor circuit arrangement comprising a semiconductor memory whose read voltage can be set.

### BACKGROUND

In order to increase the storage capacity of nonvolatile memories having a multiplicity of memory cells, a digit that represents one of more than two states, for example, four or eight states, can be stored instead of a bit which represents only one of two states. It shall be noted that a bit is a special case of a digit. The value of the digit is represented by the value of a characteristic variable, for example, a threshold voltage. Such memory cells are also referred to as multilevel memory cells.

The number of bits which can be stored in each memory cell can also be increased. In this case, each bit is represented by a characteristic variable. Such memory cells are also referred to as multibit memory cells. It is conceivable to combine these approaches by being able to store a plurality of digits in a memory cell.

So-called nitride read-only memory cells, which are also referred to as “nitride programmable read-only memory cells” or as “NROM” memory cells for short, are one possible way of storing more than one bit in a memory cell. An NROM memory cell is usually in the form of a multibit memory cell for storing two bits.

The state stored in the memory cell is usually detected using a characteristic variable which is, for example, a threshold voltage which is compared with a read voltage for the purpose of detecion.

In the case of a multiplicity of memory cells in a memory, the characteristic variables of the memory cells are in a first accumulation range in order to represent one state and are in a second accumulation range in order to represent another state.

In order to be able to distinguish the states, the read voltage must be set in such a manner that it lies between the two accumulation ranges. Threshold voltages above the read voltage are interpreted as being a first state and threshold voltages below the read voltage are interpreted as being another state.

The accumulation ranges may shift as the memory cells become older or as the number of erasing and programming cycles which have already been carried out increases.

### BRIEF DESCRIPTION OF THE DRAWINGS

The invention will be explained below using embodiments and with reference to the drawings.

FIG. 1 shows one embodiment of an NROM memory cell;

FIG. 2 shows a histogram of the threshold voltage distribution for a multiplicity of bits;

FIG. 3 shows a histogram of the threshold voltage distribution for a multiplicity of digits;

FIG. 4 shows an embodiment of a circuit arrangement;

FIG. 5 shows an embodiment of the circuit arrangement;

FIG. 6 shows a flowchart of the method; and

FIG. 7 shows a table.

### DETAILED DESCRIPTION OF ILLUSTRATIVE EMBODIMENTS

FIG. 1 shows one embodiment of an NROM cell. A doped well 255 which comprises a first doping region 201 and a second doping region 202 is made in a substrate 250. A channel region 254 is situated between the first and second doping regions 201, 202. A gate electrode 400 which is insulated from the channel region 254 by means of a dielectric layer 251, 252, 253 is arranged above the channel region 254.

The dielectric layer comprises a first oxide layer 251, a nitride layer 252 comprising silicon nitride, for example, and a second oxide layer 253. The nitride layer 252 is used as a charge trapping layer which is arranged between the insulating oxide layers 251, 253 in order to prevent diffusion of charge carriers in these directions. In further embodiments, alternative materials are used to form the charge trapping layer.

A first bit 101 and a second bit 102 can be stored in different areas of the charge trapping layer 252. A first bit region is adjacent to the first doping region and a second bit region is adjacent to the second doping region. These bits 101, 102 are indicated using ellipses in FIG. 1.

In one embodiment, the bits are programmed using so-called hot electrons. In order to erase the bit, one embodiment uses so-called hot holes which are made in the bit region and compensate for the electrons situated there.

Depending on the amount of charge introduced into the first or second bit region, a first threshold voltage which represents the first bit or a second threshold voltage which represents the second bit changes. Depending on the threshold voltage, the first or second bit represents either a logic “1” or a logic “0”.

In one embodiment, the first bit is read by applying a voltage between the first and second doping regions. A read potential of approximately 1.5 V is usually applied to the second doping region, while the first doping region is grounded, in order to read the first bit. A read voltage based on a reference potential is applied to the gate electrode. Charges close to the first doping region prevent or reduce the flow of current. In this case, the first threshold voltage is above the read voltage. In this case, the first bit represents the logic “0”. The current flows when no charge or only very few charge carriers has/have been trapped in the first bit region. In this case, the first threshold voltage is below the read voltage. The first bit represents a logic “1”. The second bit is read by applying the corresponding read potentials to the first doping region and to the gate electrode, while the second doping region is grounded.

One embodiment of a semiconductor memory usually comprises a multiplicity of memory cells. In one embodiment, the memory cells are in the form of the above-described NROM memory cells. In one embodiment, other multibit memory cells are provided. One embodiment provides memory cells which can each store only one bit. In one embodiment, the memory cells are in the form of multilevel memory cells.

The states which are stored in the memory cells are represented by characteristic variables which can be changed. The characteristic variable is usually the threshold voltage.

One embodiment of a semiconductor memory comprises a memory cell array having rows and columns which are arranged in the form of a matrix. The memory cells are coupled to word lines and bit lines. One word line from a multiplicity of word lines connects the gate electrodes of the memory cells which are arranged in one and the same row. One bit line forms the doped regions for the memory cells along two adjacent columns on each side of the bit line. Each memory cell is thus coupled to one word line and two bit lines and can be identified by selecting this word line and these bit lines.

When programming and erasing the memory cells, the threshold voltages of the memory cells are changed by applying the programming or erasing potentials. A potential which is applied to one of the word lines is applied to all of the gate electrodes of the memory cell in this row. Even if the memory cells are programmed or erased using the same potentials and the same way of applying the potentials, for example, in a pulsed manner, the distributions of the threshold voltages of the programmed and erased cells vary within a respective accumulation range. The distribution of the threshold voltages of a memory cell array having programmed and erased memory cells has two accumulation ranges, one of which represents logic “1” and the other of which represents logic “0”.

In order to be able to distinguish the states “0” and “1”, the read voltage must be set in such a manner that it lies between the two accumulation ranges. Threshold voltages above the read voltage are interpreted as logic “0” and threshold voltages below the read voltage are interpreted as logic “1”.

The accumulation ranges shift as the memory cells become older or as the number of erasing and programming cycles which have already been carried out increases. This shift usually takes place toward lower threshold voltages or the accumulation ranges move closer together.

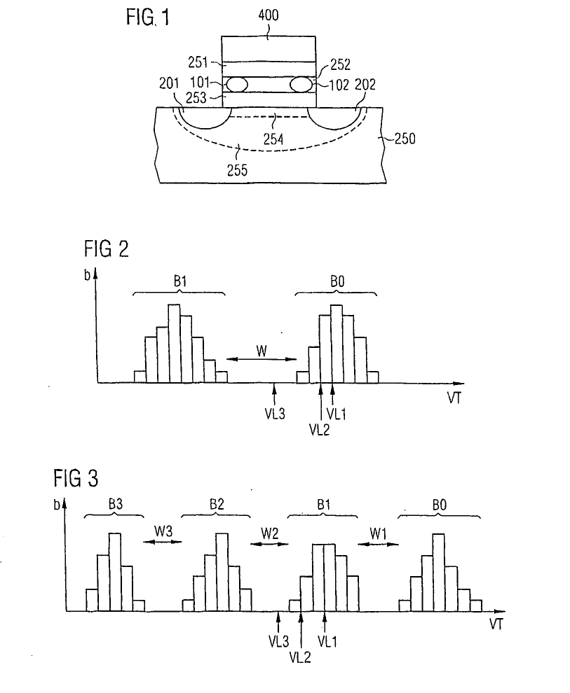

FIG. 2 illustrates a histogram of the threshold voltages for a multiplicity of memory cells. The axis caption VT indicates the threshold voltage. The axis caption b indicates the number of bits. Each bar represents the number of bits whose threshold voltage is within a range whose limits are indicated by the position and width of the bar. The distribution shows two accumulation ranges B0 and B1 which each correspond to one of the two logic states of a bit, “0” and “1”. A window W in which there are no threshold voltages VT is situated between the accumulation ranges B0, B1.

In the case of NROM memory cells, the bits which are represented by a larger threshold voltage VT are assigned to the “0”. The bits which are represented by a smaller threshold voltage VT correspond to the “1”.

When reading using a read voltage, the bits whose threshold voltage VT is above the read voltage are assigned to one logic state, “0” in this case, and the bits whose threshold voltage is below the read voltage are assigned to the other logic state, “1” in this case. For error-free reading, the read voltage must be within the window W.

The error resulting from an incorrectly aligned read voltage shall be explained below. When reading using a first read voltage VL1 which is within an accumulation range B0, only those bits whose threshold voltages VT are above the first read voltage VL1 are interpreted as “0”. Threshold voltages which are within the accumulation range B0, which represents the “0”, and are below the read voltage VL1 are incorrectly interpreted as “1”. The same effect occurs, albeit to a reduced extent, when a second read voltage VL2 which is below the first read voltage VL1 within the accumulation range B0 is used for reading.

Error-free reading is possible only when the read voltage VL is inside a window W between the two accumulation ranges B0, B1. This is the case for a third read voltage VL3.

If the read voltage is reduced in a stepwise manner, for example first of all from the first read voltage VL1 to the second read voltage VL2, the reading error is reduced with each step.

In order to be able to assess the error when setting the read voltage, the number of bits interpreted as “0” is compared with the actual value of the bits stored as “0”. If these values match, the read voltage has been set correctly.

If this number is stored in a control memory area of the memory, the problem arises, when setting the read voltage to be set, that the read voltage to be set also needs to be determined for the control memory area for error-free reading.

If bits having the logic value “0” are incorrectly read as bits having the logic value “1” in the control memory area, a higher value than the actual value is read as the number stored in the control memory area. However, the number of zeros counted when reading from memory areas is determined as being lower than the actual number on account of the same effect. The individual errors are thus opposed and cannot cancel each other out. However, the overall error, as the difference between the number represented by the control information and the number determined from the memory areas, is reduced if the read voltage is shifted in the direction of the window W.

If the window W is very narrow or the accumulation ranges overlap, it is conceivable that the error will not disappear. In these cases, the read voltage to be set is determined using the minimum error. This is effected by comparing the state information, which has been read with different read voltages, with the control information.

In one embodiment, all of the states which have been read, that is to say all of the bits which have been read and not only the number of the latter determined as being “0” or “1”, are provided for external evaluation. This information can be used to calculate a read voltage, which is to be set and for which the read error is minimal, by means of mathematical methods.

There are various procedures for selecting suitable read voltages which are used for reading for the purpose of determining the actual read voltage to be set. On the one hand, a prescribed set of read voltages, which is equivalent to scanning, can be used for reading. All of the state information is stored for subsequent evaluation.

In one embodiment, the read voltage is gradually reduced from a start value until the error between the stored value and the number determined during reading is below a prescribed value. The state information determined with the subsequent read voltages which have been gradually reduced further is stored for subsequent evaluation.

A similar method can also be used for digits which can be used to store more than one state.

FIG. 3 shows a histogram of the state distribution for a multiplicity of digits. The axis caption VT indicates the threshold voltage. The axis caption b indicates the number of bits. Each bar represents the number of bits whose threshold voltage is within a range whose limits are indicated by the position and width of the bar. Each of four accumulation ranges B0, B1, B2, B3 represents a digit state “0”, “1”, “2”, “3”. In order to distinguish the four states, three different read voltages are required and need to be respectively aligned between two accumulation ranges B0, B1 or B1, B2 or B2, B3 so that they are in one of the windows W1, W2, W3.

In order to subsequently read the states, it is necessary to determine the range between two read voltages in which the threshold voltage lies. It is thus necessary to check not only whether a threshold voltage VT is above a read voltage but also whether it is below another read voltage. This does not apply to the outer accumulation ranges B0, B3 whose threshold voltages VT are greater than or less than all of the read voltages to be set.

However, in order to set the read voltages, it is only necessary to check whether a particular number of states is above and below the read voltage. It is not necessary to precisely determine the state of the digit in this case.

This is explained below with reference to the operation of setting the read voltage between the states “1” and “2”. To this end, various read voltages VL1, VL2, VL3 are used for reading. When reading using the read voltages VL1, VL2, VL3, it is only possible to distinguish whether the threshold voltages VT which represent the states of the digits are above or below the corresponding read voltage VL1, VL2, VL3. In the case of error-free reading, the former belong to a first state set having the states “0” and “1” and the latter belong to a second state set having the states “2” and “3”. Each reading step using one of the read voltages VL1, VL2, VL3 determines how many of the digits are read as belonging to the first state set and/or to the second state set.

If the read voltage is selected in such a manner that it is within the accumulation range B 1 which represents the “1”, some of these threshold voltages will be incorrectly read as belonging to the second state set. This is the case with the read voltages VL1 and VL2 in FIG. 3.

The read voltage to be set is determined by comparing the number of states which have been read as belonging to the first state set with the number of states which actually belong to the first state set. This number can be stored in a control memory area. Errors when reading this control memory are reduced if the read voltage is reduced in the direction of the corresponding window, as already described above for bits.

In the case of digits, a counter and a control memory area need to be provided for each read voltage to be set. The first state set comprises the states having a threshold voltage above the read voltage to be set and the second state set comprises the states having a threshold voltage below the read voltage to be set.

One embodiment of a method provides for setting a read voltage which is used to read data from a nonvolatile memory comprising memory cells. At least one digit having a state from a first and a second state set can be stored in each memory cell. The first state set comprises at least one first state and the second state set comprises at least one second state. Groups of digits are each assigned to one memory area from a multiplicity of memory areas in the memory. The method comprises: storing logic states from the first state set in a particular number of digits in the multiplicity of memory areas; reading the memory areas in succession, the operation of reading one of the memory areas involving a plurality of reading steps for reading state information, the read voltage being varied for each reading step and the state information which has been read being provided after each reading step; providing control information based on the particular number of digits; comparing the state information which has been provided with the control information; determining the read voltage to be set or a read voltage range to be set on the basis of the results of the comparison.

In one embodiment, the read voltage to be set or a read voltage within the read voltage range to be set is used to read the data from the memory cells during normal operation of the memory.

The method for setting the read voltage ensures that accumulation ranges can be distinguished even when they have been shifted.

The practice of reading a memory area a number of times using a read voltage which is respectively changed in a stepwise manner when reading the memory areas is more efficient in terms of time and energy than first of all reading all of the memory areas in succession using a read voltage, then varying the read voltage and then reading all of the memory areas again. This is based on the fact that only the read voltage which is applied to the word lines has to be varied based on a reference potential for each reading step.

Each memory area is read using different read voltages during the reading step. Depending on whether the digits in the memory area are represented by threshold voltages above or below the read voltage, the state of said digits is classified as belonging to the first or second state set. This shall be explained for the case of an NROM memory cell: threshold voltages above the read voltage are interpreted as logic “0” and the other voltages are interpreted as logic “1”. The reverse assignment is also conceivable. The number of detected “0” in the memory area or the number of digits whose state is interpreted as belonging to the first state set thus changes as the read voltage is changed.

If more than two states can be represented by a digit, a plurality of read voltages need to be set. In order to set one of the read voltages, the state sets are each adapted to the effect that one of the state sets comprises states whose characteristic variables are intended to be above the read voltage to be set.

In one embodiment, digits are stored in a control memory area. The states of the digits represent, as control information, the number of stored states which are included in one of the state sets. This control information can be used to determine the read voltage to be set. In this case, the control information which has been read is compared with the number of states within the state set which has been read from the memory areas. The result indicates the read voltage which is to be set and for which the greatest match between the control information and the number which has been read occurs.

In one embodiment, the read voltage for the memory areas as well as the read voltage for the control memory areas are each changed in a stepwise manner from a start value, so that the same read voltages are checked for all areas.

In this case, read errors occur both in the control memory area and in the memory areas in the case of a read voltage which is within one of the accumulation ranges. However, the errors for the control memory area and for the memory areas do not cancel each other out but rather are opposed. The difference between the number which has been read and the control information becomes smaller as the read voltage is increasingly adapted and is equal to zero at best.

Simultaneously reading the memory cells in a memory area or in the control memory area increases the speed of the reading operation.

One embodiment of a semiconductor circuit arrangement having a read voltage which can be set comprises a nonvolatile semiconductor memory comprising memory cells, at least one digit having a state from a first state set and a second state set being able to be stored in each memory cell, the first state set comprising at least one first state and the second state set comprising at least one second state, and groups of digits each being assigned to one memory area from a multiplicity of memory areas in the memory. The semiconductor circuit arrangement also comprises a word line decoder which is coupled to the semiconductor memory and is designed to access the memory areas, a multiplicity of sense amplifiers which are coupled to the semiconductor memory and are designed to read the memory cells whose digits are assigned to one of the memory areas, a read voltage control unit which is coupled to the multiplicity of sense amplifiers and is designed to provide a read voltage which can be changed and is intended for the reading operation, a control device which is coupled to the word line decoder and to the read control unit and is designed to drive the latter in such a manner that the memory areas are accessed in succession in such a way that, when one of the memory areas is accessed, it is read a number of times using a read voltage which is changed in each case, and a detection means which is coupled to the multiplicity of sense amplifiers and is designed to provide state information of the digits stored in the memory area which has been read.

In this embodiment, in order to set the read voltage, each of the memory areas is first read using different read voltages, which is associated with a time saving.

One embodiment provides an evaluation device which is used to evaluate the read voltage to be set or a read voltage range to be set using the different read voltages.

The detection means provides, as state information, the fact of whether the digits in the memory area which has been read can be assigned to the first state set. This information can be used to infer the correctness of the information which has been read by comparing it with the control information.

In one embodiment, the detection means comprises a counter in order to determine the number of digits which have been read and can be assigned to the first state set. This information can be compared with the number of digits which were originally stored and can be assigned to the first state set. A comparison apparatus is provided for this purpose.

In one embodiment, the control information can be provided by a control memory area.

One embodiment of the semiconductor circuit arrangement comprises a memory means in order to store the state information assigned to the respective read voltages. The read voltage to be set is determined by evaluating this state information.

In one embodiment, this memory means is configured in such a manner that the number of states which can be assigned to the first state set is stored, as state information, for each memory area and for each read voltage.

An adder makes it possible to determine the total number of numbers which have been read for all memory areas with a read voltage.

In one embodiment, an external controller is provided with the state information which has been read using the different read voltages in order to determine the actual read voltage to be set within the read voltage range determined. In this case, the state information comprises the data detected using the different read voltages. These data may comprise all stored data records which have been read using the different read voltages within the read voltage range. The external controller is designed to use mathematical methods to determine the optimum read voltage within the read voltage range for which the probability of errors is lowest.

In one embodiment, the memory areas comprise NROM memory cells in which two bits can respectively be stored, which is associated with a space-saving design of the memory areas.

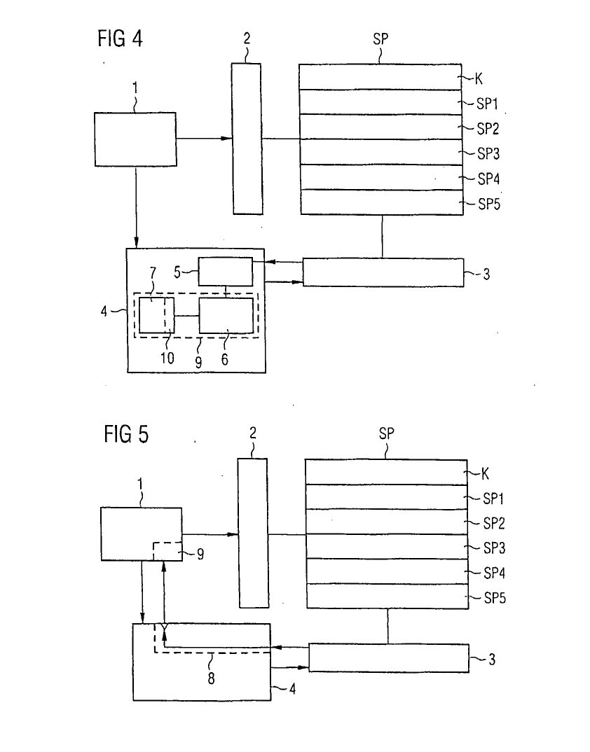

FIG. 4 shows one embodiment of a circuit arrangement having a read voltage which can be aligned. The circuit arrangement comprises a memory SP having a multiplicity of memory cells.

The memory SP comprises a plurality of memory areas SP1, SP2, SP3, SP4, SP5. Digits which can be stored in the memory SP are assigned to one of the memory areas SP1, SP2, SP3, SP4, SP5. Furthermore, the memory SP also comprises a control memory area K in which digits can likewise be stored. It shall be noted that, when the text refers to “digits”, the corresponding statements also apply below to digits having two possible states, that is to say “bits”.

One conceivable organization of such a memory may comprise so-called pages having a multiplicity of so-called words. The control memory area K comprises one word, preferably the first word on the page, and the memory areas SP1, SP2, SP3, SP4, SP5 each comprise the remaining words on the page. The memory cells assigned to the words are coupled to a word line.

The memory SP is coupled to a word line decoder 2. The word line decoder 2 is designed to identify and select the memory areas SP1, SP2, SP3, SP4, SP5 for reading.

Furthermore, the memory SP is coupled to a multiplicity of sense amplifiers 3. The sense amplifiers 3 read the digits in a memory area SP1, SP2, SP3, SP4, SP5 in a parallel manner. This is achieved by virtue of a sense amplifier 3 being allocated to each memory cell in the memory area SP1, SP2, SP3, SP4, SP5. The sense amplifiers 3 are used to provide a read voltage which can be applied by means of the word lines.

The read voltage is set by a read voltage control unit 4 which is coupled to the sense amplifiers 3.

A control device 1 which is designed to access the digits or the corresponding memory cells in the memory areas SP1, SP2, SP3, SP4, SP5 is coupled to the read voltage control unit 4 and to the word line decoder 2.

The read voltage control unit 4 comprises a counter 5 which is coupled to an evaluation device 9 having a memory 6 and a comparison device 7.

In order to read state information during normal operation, the read voltage which has been set is applied to the memory cells of the selected word. A current which flows or does not flow is used to indicate whether the threshold voltages of the corresponding memory cells are above or below the read voltage. This indicates the state of the memory cells and the stored digits. If the threshold voltage represents a bit, the state is directly indicated. If the digit represents one of more than two states, each possible state is assigned to a threshold voltage range. A plurality of comparison steps are needed to determine that range of these ranges in which the threshold voltage value lies. If, for example, the digit can assume one of four states, three read voltages are required.

The text below discusses the operation of setting a read voltage. Further read voltages to be set can be aligned in a corresponding manner. To this end, the memory areas SP1, SP2, SP3, SP4, SP5 are read in succession using a varied read voltage.

The reading operation comprises a plurality of reading steps for each memory area SP1, SP2, SP3, SP4, SP5, the read voltage being varied for each of the reading steps. After a memory area has been read using a plurality of read voltage values, one of the other memory areas is read in the same manner. The procedure is repeated for each of the memory areas SP1, SP2, SP3, SP4, SP5 until all of the memory areas SP1, SP2, SP3, SP4, SP5 have been read in this manner.

The states which are read with each reading step are counted by the read voltage control unit 4 using the counter 5, so that the number of digits in the memory area which are represented by threshold voltages above the read voltage is determined. Alternatively, the counter 5 can also determine the number of digits in the memory area which are represented by threshold voltages below the read voltage.

These values are stored in a memory device, for example a volatile memory 6 or a register, in such a manner that the values can be assigned to the read voltage with which reading was effected. In one embodiment, storage is effected in the form of a table. In order to determine the read voltage to be set, the results of the individual memory areas for the same read voltage can be summed using an adder 10.

Comparing the values determined using the counter with the actual number of threshold voltages which should be above the read voltage makes it possible to determine the read voltage which is to be set and for which the difference disappears or is smallest. The comparison device 7 is provided for this purpose.

The actual number can be stored in the control memory area K. If the control memory area K is read in the same manner, that is to say using the same read voltages, as the other memory areas SP1, SP2, SP3, SP4, SP5, read errors also occur in this case. However, the difference between this error and the error when reading the memory areas disappears following correct alignment of the read voltage so that the latter is in a window between the accumulation ranges.

Alternatively, in the case of bits, it is possible to determine the start value, from which the read voltages are modified for the reading steps, on the basis of redundant information in the control memory. In this case, in addition to the number of logic “0” stored in the memory areas SP1, SP2, SP3, SP4, SP5, the inverse of this is also stored, with the result that the number of logic “0” and the number of logic “1” in the control memory area are the same. The control memory is then first of all read using a varied read voltage until the number of “0” read and the number of “1” read are the same. The corresponding read voltage is used as the start value for the actual method for setting the read voltage.

FIG. 5 shows an alternative embodiment of the semiconductor circuit arrangement. The same reference symbols indicate the same parts of the arrangement. In order to avoid repetition, corresponding arrangements are not described a number of times.

In this embodiment, the optimum read voltage is not determined by the read voltage control device 4. The read voltage control device 4 merely uses a detection means 8 to provide the state information, which has been read by the sense amplifiers 3, for further evaluation. The actual evaluation is carried out, for example, by an evaluation device 9 in the control device 1 or by an external device. As a result of the provision, the compression step carried out by the counter is dispensed with. Rather, state information is provided for all digits in the memory areas which have each been read with a multiplicity of read voltages. More complex and more accurate evaluation can be carried out on account of this quantity of data.

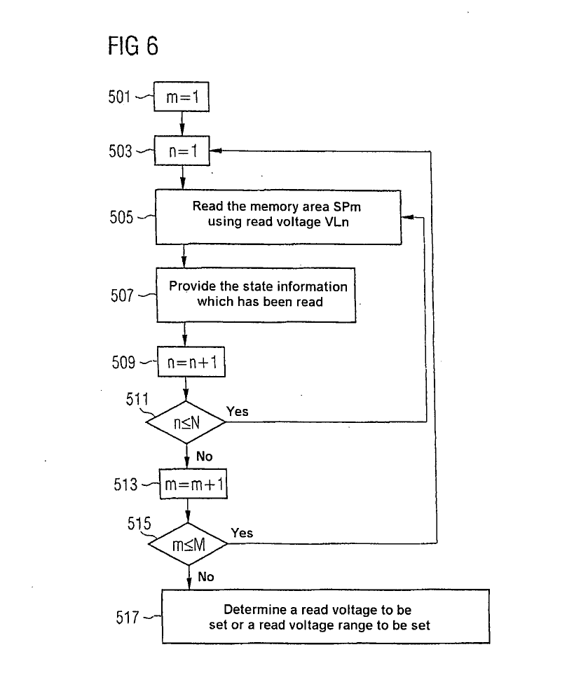

FIG. 6 illustrates the sequence involved in reading the memory areas in one embodiment.

The memory comprises M memory areas SPm which are each read using N different read voltages VLn. At the beginning 501, 503, the first memory area SP1 is read using the first read voltage VL1 in step 505. The state information that has been read and is provided in step 507 may comprise the states themselves which have been read in their processed form. For the latter, the number of “0” in this memory area SP1 read with this read voltage VL1 can be determined and stored in a table, for example.

If all of the read voltages VLn to be investigated have not yet been applied, as illustrated in blocks 509, 511, the memory area SP1 is read using the next read voltage, now VL2, and the state information is provided. This is repeated until the memory area SP1 has been read using all of the read voltages VL1 to VLn.

In order to save time, the read voltage is adapted in such a manner that a memory area SP1 is first of all read with different read voltages VLn. For these steps, it is not necessary to change the read voltages which are applied to the bit lines. Only the read voltage VLn which is applied to the word line is varied. This is effected by means of appropriate driving using the read voltage control device 4.

In the following step, if all of the memory areas SPm have not yet been read, as illustrated in blocks 513, 515, the next memory area, SP2 in this case, is read using the read voltages VL1 to VLn.

These steps 503, 505, 507, 509, 511, 513, 515, in particular the reading and providing steps 505, 507, are repeated until all memory areas SP1 to SPm have been read.

In the concluding step 517, the read voltage to be set or the read voltage range to be set is determined.

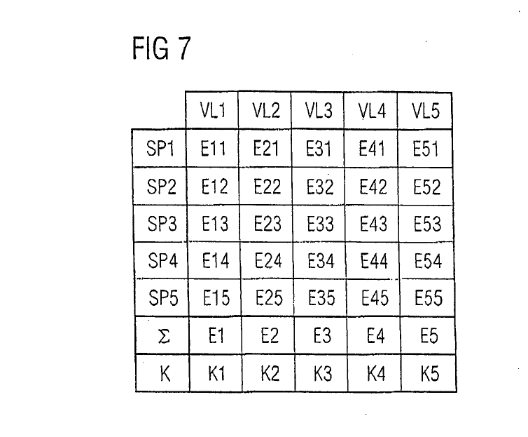

FIG. 7 shows a table which makes it possible to determine the read voltage to be set. The values, for example the numbers of “0” read, for one and the same read voltage VLn for the different memory areas SP1, SP2, SP3, SP4, SP5 are entered in the columns. Only five memory areas SP1, SP2, SP3, SP4, SP5 are illustrated by way of example. The number of memory areas read is usually greater. The table illustrates five read voltages VL1, VL2, VL3, VL4, VL5 by way of example. The rows illustrate the values for one and the same memory area SPm for the different read voltages VL1, VL2, VL3, VL4, VL5. The entry E41 indicates, for example, the number of “0” in the first memory area SP1 for the fourth read voltage VL4.

The number stored in the control memory area K is also read as control information K1, K2, K3, K4, K5 for the different read voltages VL1, VL2, VL3, VL4, VL5. The numbers K1, K2, K3, K4, K5 which have been read can vary on the basis of the read voltage VL1, VL2, VL3, VL4, VL5. They are entered in one row of the table.

In order to determine the read voltage to be set, the entries in the columns are added, for example E11 to E15, and the results E1, E2, E3, E4, E5 are compared with the number of actually stored “0” or the number which has been read from the control memory area K, K1 in this case, for the respective read voltage, VL1 in this case. The entry or entries with the best match indicate(s) the read voltage to be set or the read voltage range to be set.

What is claimed is:

1. A method for setting a read voltage to be used to read data from a nonvolatile memory comprising memory cells, at least one digit having a state from a first and a second state set being able to be stored in each memory cell, the first state set comprising at least one first state and the second state set comprising at least one second state, and groups of digits each being assigned to one memory area from a multiplicity of memory areas in the memory, said method comprising:
storing logic states from the first state set in a particular number of digits in the multiplicity of memory areas;
reading the memory areas in succession, the operation of reading one of the memory areas comprising a plurality of reading steps for reading state information, the read voltage being varied for each reading step and the state information which has been read being provided after each reading step;
providing control information based on the particular number of digits;
comparing the state information which has been provided with the control information; and
determining the read voltage to be set or a read voltage range to be set on the basis of the results of the comparison.

2. The method as claimed in claim 1, wherein digits having states that represent the particular number are stored as control information in memory cells of a control memory area.

3. The method as claimed in claim 2, wherein the control information is read in a plurality of reading steps using the read voltage, which is changed for each reading step, and is provided after each reading step.

4. The method as claimed in claim 1, wherein the state information of one of the memory areas is simultaneously read from corresponding memory cells.

5. The method as claimed in claim 2, wherein the control information of the control memory area is simultaneously read from corresponding memory cells.

6. The method as claimed in claim 1, wherein determining the read voltage to be set or the read voltage range to be set comprises comparing the state information that has been read from all of the memory areas with the control information.

7. The method as claimed in claim 2, wherein the operation of determining the read voltage to be set or the read voltage range to be set comprises comparing the control information, which has been read from the control memory with a read voltage, with the state information which has been read from all of the memory areas with the same read voltage.

8. The method as claimed in claim 7, wherein the state information which has been read comprises the number of states that have been read and can be assigned to the first state set.

9. The method as claimed in claim 8, wherein the numbers that have been read with the same read voltage are summed for all memory areas.

10. The method as claimed in claim 1, wherein an external controller is provided with state information that has been read using the different read voltages within the read voltage range, said controller determining the read voltage to be set.

11. The method as claimed in claim 1, further comprising using the read voltage to be set or a read voltage within the read voltage range to be set to read the data from the memory cells during normal operation of the memory.

12. A method for setting a read voltage that is used to read data from memory areas having memory cells, at least one bit being able to be stored in each memory cell, and groups of bits each being assigned to one of the memory areas, said method comprising:
storing a particular number of bits, which have a first state, in the memory areas;
reading the memory areas in succession, the operation of reading one of the memory areas comprising a plurality of reading steps for reading state information, a read voltage being varied for each reading step and the state information that has been read being provided after each reading step;
providing control information that comprises the particular number of bits;
comparing the state information that has been provided with the control information;
using the results of the comparison to determine the read voltage to be set or a read voltage range to be set; and
using the read voltage to be set or a read voltage within the read voltage range to be set to read the data from the memory cells during normal operation of the memory.

13. The method as claimed in claim 12, further comprising storing the control information in memory cells of a control memory area.

14. The method as claimed in claim 13, further comprising reading the control information in a plurality of reading steps using the read voltage that is changed for each reading step and providing the control information after each reading step.

15. The method as claimed in claim 12, wherein determining the read voltage to be set or the read voltage range to be set comprises comparing the state information that has been read from all of the memory areas with the control information.

16. The method as claimed in claim 13, wherein determining the read voltage to be set or the read voltage range to be set comprises comparing the control information, which has been read from the control memory with a read voltage, with the state information that has been read from all of the memory areas with the same read voltage.

17. The method as claimed in claim 16, wherein the state information that has been read comprises the number of bits that have been read and have the first state.

18. The method as claimed in claim 17, wherein the numbers that have been read with the same read voltage are summed for all memory areas.

19. A semiconductor circuit arrangement comprising:
a nonvolatile semiconductor memory comprising memory cells, at least one digit having a state from a first state set and a second state set being able to be stored in each memory cell, the first state set comprising at least one first state and the second state set comprising at least one second state, and groups of digits each being assigned to one memory area from a multiplicity of memory areas in the semiconductor memory;
a word line decoder coupled to the semiconductor memory and designed to access the memory areas;
a multiplicity of sense amplifiers coupled to the semiconductor memory and are designed to read the memory cells whose digits are assigned to one of the memory areas;
a read voltage control unit coupled to the multiplicity of sense amplifiers and is designed to provide a read voltage that can be changed and is intended for the reading operation;
a control device coupled to the word line decoder and to the read voltage control unit and designed to drive the read voltage control unit in such a manner that the memory areas are accessed in succession in such a way that, when one of the memory areas is accessed, it is read a number of times using a read voltage that is changed in each case; and
a detector means coupled to the multiplicity of sense amplifiers and designed to provide state information of the digits stored in the memory area that has been read.

20. The semiconductor circuit arrangement as claimed in claim 19, further comprising an evaluation device coupled to the detector and designed to evaluate the state information with regard to a read voltage to be set or a read voltage range to be set.

21. The semiconductor circuit arrangement as claimed in claim 19, wherein the detector provides, as state information, the fact of whether the digits in the memory area that has been read can be assigned to the state or states of the first state set.

22. The semiconductor circuit arrangement as claimed in claim 19, wherein the detector comprises a counter that provides, as state information, the number of digits in the memory area that has been read that can be assigned to states of the first state set.

23. The semiconductor circuit arrangement as claimed in claim 20, wherein the evaluation device comprises a memory designed to store the state information assigned to the corresponding read voltages.

24. The semiconductor circuit arrangement as claimed in claim 23, wherein the evaluation device comprises an adder in order to sum the numbers that are stored in the memory and are assigned to the same read voltage.

25. The semiconductor circuit arrangement as claimed in claim 24, wherein the evaluation device comprises a comparator coupled to the memory and to the adder, the comparator designed to compare the sum with a value or with a plurality of values.

26. The semiconductor circuit arrangement as claimed in claim 19, wherein the semiconductor memory comprises a control memory area designed to store states that represent the number of digits that have states from the first state set and are stored in the memory areas.

27. The semiconductor circuit arrangement as claimed in claim 26, wherein said circuit arrangement accesses the control memory area, with the result that, when the control memory area is accessed, it is read a number of times using a read voltage that is changed in each case.

28. The semiconductor circuit arrangement as claimed in claim 27, wherein the memory is designed to store the state information from the control memory area assigned to the corresponding read voltages.

29. The semiconductor circuit arrangement as claimed in claim 28, wherein the comparator is designed to compare the sum with state information from the control memory area.

30. A semiconductor circuit arrangement comprising:
a nonvolatile semiconductor memory comprising memory cells, at least one bit being able to be stored in each memory cell, and groups of bits each being assigned to one memory area from a multiplicity of memory areas in the semiconductor memory;
a word line decoder coupled to the semiconductor memory and designed to access the memory areas;
a plurality of sense amplifiers coupled to the semiconductor memory and designed to read the bits that are assigned to one of the memory areas;
a read voltage control unit coupled to the plurality of sense amplifiers and designed to provide a read voltage that can be changed and is intended for the reading operation;
a control device coupled to the word line decoder and to the read voltage control unit and designed to drive the read voltage control unit in such a manner that the memory areas are accessed in succession in such a way that, when one of the memory areas is accessed, it is read a number of times using a read voltage that is changed in each case;
a detector coupled to the plurality of sense amplifiers and designed to provide state information of the bits stored in the memory area that has been read; and
an evaluation device coupled to the detector and designed to evaluate the state information with regard to a read voltage to be set or a read voltage range to be set.

31. The semiconductor circuit arrangement as claimed in claim 30, wherein the detector detects a number of bits that have been read and have a first state.

32. The semiconductor circuit arrangement as claimed in claim 30, wherein the evaluation device comprising a memory that stores the state information assigned to the corresponding read voltages.

33. The semiconductor circuit arrangement as claimed in claim 32, wherein the evaluation device comprises an adder in order to sum the numbers that are stored in the memory and are assigned to the same read voltage.

34. The semiconductor circuit arrangement as claimed in claim 33, wherein the evaluation device comprises a comparison device that is coupled to the memory and to the adder and is designed to compare the sum with a value or with a plurality of values.

35. The semiconductor circuit arrangement as claimed in claim 30, wherein the semiconductor memory comprises a control memory area designed to represent the number of bits in the memory areas that have a first state.

36. The semiconductor circuit arrangement as claimed in claim 35, wherein said circuit arrangement accesses the control memory area, with the result that, when the control memory area is accessed, it is read a number of times using a read voltage which is changed in each case.

37. The semiconductor circuit arrangement as claimed in claim 36, wherein the memory is designed to store the state information from the control memory area assigned to the corresponding read voltages.

38. The semiconductor circuit arrangement as claimed in claim 37, wherein the comparison device is designed to compare the sum with state information from the control memory area.

39. The semiconductor circuit arrangement as claimed in claim 30, wherein the memory cells comprise NROM memory cells.
